(19) United States
(12) Patent Application Publication
(10) Pub. No.: US 2022/0199547 A1
(43) Pub. Date: Jun. 23, 2022

(54) FAN-OUT WAFER-LEVEL PACKAGING (FOWLP) INTEGRATED CIRCUITS (ICs) EMPLOYING AN ELECTRO-MAGNETIC INTERFERENCE (EMI) SHIELD STRUCTURE IN UNUSED FAN-OUT AREA FOR EMI SHIELDING, AND RELATED FABRICATION METHODS

(71) Applicant: QUALCOMM Incorporated, San Diego, CA (US)

(72) Inventors: Li-Sheng Weng, San Diego, CA (US); Yu-Chih Chen, San Diego, CA (US); Chaoqi Zhang, San Diego, CA (US)

(21) Appl. No.: 17/127,750

(22) Filed: Dec. 18, 2020

(51) Int. Cl. H01L 23/552; H01L 23/00

(52) U.S. Cl. CPC H01L 23/552; H01L 2924/3025; H01L 24/20; H01L 24/19

(57) ABSTRACT

Fan-out wafer-level packaging (FOWLP) integrated circuits (ICs) employing electro-magnetic (EM) interference (EMI) shield structure in fan out area for EMI shielding, and related fabricating methods are disclosed. The IC includes a semiconductor die (“IC die”) that is bonded to the reconstituted carrier wafer such that a fan-out area is provided between adjacent IC dies to provide area for fan-out interconnects to provide additional die interconnections to the IC die. In exemplary aspects, the IC includes an EMI shield that includes vias formed in an un-used area in fan-out area adjacent to the IC die electrically that are otherwise unused for input/output (I/O) signal interconnects for coupling I/O signals to the IC die. The EMI shield is electrically coupled to a ground node of the IC die to provide an effective EMI shield to block or attenuate unwanted EM noise propagated from the IC die outside the IC.

### BACKGROUND

### I. Field of the Disclosure

The field of the disclosure relates to integrated circuits (ICs), such as wafer-level packaging (WLP) ICs that an IC die that produces electro-magnetic (EM) noise that can propagate outside the IC die and cause unwanted electro-magnetic interference (EMI).

### II. Background

Integrated circuits (ICs) are the cornerstone of most modern day electronic devices. ICs are microscopic arrays of electronic circuits and components made together or integrated; hence the name. Initially, ICs held only a few devices, probably as many as ten diodes, transistors, resistors, and capacitors that allow the IC to fabricate one or more logic gates. Today, very-large-scale integration (VLSI) has created ICs with millions of gates and hundreds of millions of individual transistors. ICs are found in devices such as computers and cellular phones. Over the years, scientists have significantly reduced the size of IC's. In turn, these smaller ICs bring about smaller electronic devices. The decrease in the size of ICs over the years has been so dramatic that to decrease their size even further is made difficult by physical limitations found at micro- and nanometer levels.

Fan-out wafer-level packaging (FOWLP) is an enhancement of standard WLP developed to provide a solution for semiconductor devices requiring a higher integration level and a greater number of external contacts. It also provides a smaller package footprint with higher input/output (I/O), along with better thermal and electrical performance than standard WLP. In conventional WLP (also referred to as “fan-in” WLP), I/O terminals can only be located within the footprint of the semiconductor device on the wafer. Using this method, there is a limit to the number of I/O connections that a given semiconductor device can have. In contrast, fan-out WLP (FOWLP) takes individual semiconductor devices and embeds them in a low-cost material, such as epoxy mold compound (EMC), with space allocated between each semiconductor device for additional I/O connection points. In this manner, I/O connections for a given semiconductor device can “fan out” from the footprint of the semiconductor device on the wafer. The “fan out” occurs in the redistribution layers (RDLs) of a wafer. RDLs can be formed on the wafers using particle vapor deposition (PVD) and subsequent electroplating/patterning to re-route I/O connections of a semiconductor device to the package balls (a.k.a. “solder balls,” “solder bumps,” or “bumps”).

WLP ICs can include ICs that are noisy, meaning these ICs emit electro-magnetic (EM) noise. For example, a WLP IC may include a power management IC that includes power switching circuitry that provides power to other ICs in the WLP. The power management IC may emit EM fields as EM “noise” due to the frequency switching off and on of power in the power switching circuitry. This noise is propagated through EM propagation to other circuits, such radio-frequency (RF) circuits and/or circuit routings in the WLP, thus causing electro-magnetic interference (EMI) in such other circuits and/or circuit routings. EMI can degrade system performance and power signals in other circuits in the WLP.

### SUMMARY OF THE DISCLOSURE

Aspects disclosed herein include fan-out wafer-level packaging (FOWLP) integrated circuits (ICs) employing an electro-magnetic (EM) interference (EMI) shield structure in an unused fan-out area for EMI shielding. Related fabrication methods are also disclosed. The IC includes a semiconductor die (“IC die”) that is formed by a FOWLP process wherein the IC die is fabricated on a semiconductor wafer, singulated, and bonded to another overmolded reconstituted carrier wafer. The IC die is bonded to the reconstituted carrier wafer such that a fan-out area is provided between adjacent IC dies to provide an area for fan-out interconnects to be formed and electrically coupled to the IC die to provide additional die interconnections to the IC die. In exemplary aspects disclosed herein, the IC includes an EMI shield that includes vias formed in unused areas in a fan-out area adjacent to the IC die that are not otherwise used for input/output (I/O) signal interconnects for coupling I/O signals to the IC die. The EMI shield is electrically coupled to a ground node of the IC die to provide an effective Faraday EMI shield to block or attenuate unwanted EM noise propagated from the IC die outside the IC. By using the unused areas in the fan-out area forming the vias of the EMI shield, the EMI shield can be formed for the IC die as part of the fabrication process of the IC die. Further, additional area and cost can be avoided in providing EMI shields and/or compartmentalized metal structures in the IC package to electro-magnetically shield the IC die.

In other exemplary aspects, the EMI shield can include one or more via array structures formed in fan-out areas that are unused for I/O signal interconnects on one or more sides adjacent to the IC die. For example, it may be desired to form a via array structure in unused areas of the fan-out areas on each side of the IC die to form a fully side-enclosed EMI shield. The IC can also include an optional conductive layer on the backside of the IC die electrically coupled to a via array structure(s) to form part of the EMI shield.

In other exemplary aspects, a fabrication process is provided to fabricate the FOWLP IC. In exemplary aspects, the vias of a via array structure are formed in a reconstituted carrier wafer before IC dies are mounted to the reconstituted carrier wafer and overmolded to form an EMI shield. The vias of the via array structure can be formed in patterned openings in a dielectric layer of the reconstituted carrier wafer that are aligned in what will be an unused areas in the fan-out area when the reconstituted IC dies are placed on the reconstituted carrier wafer. A metallization layer(s) is formed on the active side of the placed IC dies on the reconstituted carrier wafer. A ground node or layer of the metallization layer(s) of each reconstituted IC die is formed in electrical contact with its respective via array structure such that the via array structure will form an EMI shield for its respective IC die.

In this regard, in one exemplary aspect, an IC is provided. The IC comprises an IC die comprising a plurality of die sides. The IC die comprises an active semiconductor layer disposed in a horizontal plane. The IC die also comprises a metallization structure comprising a plurality of die interconnects electrically coupled to the active semiconductor layer. The IC also comprises one or more I/O signal fan-out interconnects each disposed in an fan-out area among one or more fan-out areas each adjacent to a different die side among the plurality of die sides of the IC die in the horizontal plane. The one or more I/O signal fan-out interconnects are electrically coupled to one or more die interconnects among the plurality die interconnects. The IC also comprises an EMI shield comprising one or more vias each disposed in a fan-out area among the one or more fan-out areas.

In another exemplary aspect, a method of fabricating an IC is provided. The method comprises forming a metal seed layer disposed on a carrier. The method also comprises forming an EMI shield. Forming the EMI shield comprises forming one or more vias in a fan-out area among one or more unused fan-out areas. The method also comprises forming an IC die comprising a plurality of die sides. The method of forming the IC die comprises forming an active semiconductor layer disposed in a horizontal plane, forming a metallization structure comprising a plurality of die interconnects electrically coupled to the active semiconductor layer, and disposing the IC die on the carrier such that the one or more fan-out areas are each adjacent to a different die side among the plurality of die sides.

### BRIEF DESCRIPTION OF THE FIGURES

FIGS. 1A and 1B are side and top views, respectively, of an integrated circuit (IC) package that includes a die module with a plurality of IC chips mounted on a package substrate and employing an electro-magnetic interference (EMI) shield compartmentalized by metal cans for individual IC chips;

FIG. 2 is a perspective view of an exemplary reconstituted carrier wafer formed from a fan-out wafer-level packaging (FOWLP) process, wherein the reconstituted carrier wafer includes a plurality of reconstituted semiconductor dies (“IC dies”) with fan-out connections formed in a semiconductor wafer in a fan-out area adjacent to the IC dies and electrically coupled to respective reconstituted IC dies for providing external connections;

FIGS. 3A-3C are perspective, bottom, and side views, respectively, of an exemplary FOWLP IC that includes an IC die with fan-out interconnects in a fan-out area adjacent to and electrically coupled to the IC die for providing external connections, and wherein the FOWLP IC also includes vias formed in a fan-out area of the IC that is otherwise unused for fan-out input/output (I/O) signal interconnects to form an EMI shield for the IC die;

FIG. 4A is a side view of an exemplary FOWLP IC that includes an IC die and that does not include vias formed in a fan-out area of the IC that is otherwise unused for fan-out I/O signal interconnects to form an EMI shield for the IC die;

FIG. 4B is a side view of an exemplary FOWLP IC that includes a FOWLP IC that includes vias formed in a fan-out area of the IC that is otherwise unused for fan-out I/O signal interconnects to form an EMI shield for the IC die;

FIG. 5A is a diagram illustrating exemplary H-field emission by an IC die in a FOWLP IC that does not include vias formed in a fan-out area of the IC that is otherwise unused for fan-out I/O signal interconnects to form an EMI shield for the IC die, including, but not limited to, the FOWLP ICs in FIGS. 3A-3C and 4B;

FIG. 5B is a diagram illustrating exemplary H-field emission by the IC die in the FOWLP IC in FIG. 4B;

FIGS. 6A-6J illustrate exemplary fabrication stages of an exemplary process of fabricating a FOWLP IC that includes vias formed in a fan-out area of the IC that is otherwise unused for fan-out I/O signal interconnects to form an EMI shield for the IC die, including, but not limited to, the FOWLP ICs in FIGS. 3A-3C and 4B;

FIGS. 7A-7D are a flowchart illustrating an exemplary process of fabricating the FOWLP IC that includes a via array structure formed in a FOWLP periphery area adjacent to a fan-out area of an IC die to form an EMI shield for the IC die according to the fabrication stages in FIGS. 6A-6J;

FIG. 8 is a flowchart illustrating an exemplary process of fabricating a FOWLP IC that includes that includes vias formed in a fan-out area of the IC that is otherwise unused for fan-out I/O signal interconnects to form an EMI shield for the IC die, including, but not limited to, the FOWLP ICs in FIGS. 3A-3C and 4B;

FIG. 9 is a block diagram of an exemplary wireless communications device that includes radio-frequency (RF) components provided in one or more FOWLP ICs that include an IC die with fan-out interconnects in a fan-out area adjacent to and electrically coupled to the IC die for providing external connections, and wherein the FOWLP IC also includes vias formed in the fan-out area that is otherwise unused for fan-out I/O signal interconnects to form an EMI shield for the IC die, including, but not limited to, the FOWLP ICs in FIGS. 3A-3C and 4B, and according to any of the fabrication processes in FIGS. 6A-8; and

FIG. 10 is a block diagram of an exemplary processor-based system that can be provided in in one or more one or more FOWLP ICs that include an IC die with fan-out interconnects in a fan-out area adjacent to and electrically coupled to the IC die for providing external connections, and wherein the FOWLP IC also includes vias formed in the fan-out area that is otherwise unused for fan-out I/O signal interconnects to form an EMI shield for the IC die, including, but not limited to, the FOWLP ICs in FIGS. 3A-3C and 4B, and according to any of the fabrication processes in FIGS. 6A-8.

### DETAILED DESCRIPTION

With reference now to the drawing figures, several exemplary aspects of the present disclosure are described. The word “exemplary” is used herein to mean “serving as an example, instance, or illustration.” Any aspect described herein as “exemplary” is not necessarily to be construed as preferred or advantageous over other aspects.

Aspects disclosed herein include fan-out wafer-level packaging (FOWLP) integrated circuits (ICs) employing electro-magnetic (EM) interference (EMI) shield structure in fan out area for EMI shielding. Related fabricating methods are also disclosed. The IC includes a semiconductor die (“IC die”) that is formed by a FOWLP process wherein the IC die is fabricated on a semiconductor wafer, singulated, and bonded to another overmolded reconstituted carrier wafer. The IC die is bonded to the reconstituted carrier wafer such that a fan-out area is provided between adjacent IC dies to provide area for fan-out interconnects to be formed and electrical coupled to the IC die to provide additional die interconnections to the IC die. In exemplary aspects disclosed herein, the IC includes an EMI shield that includes vias formed in an un-used areas in fan-out area adjacent to the IC die that are not otherwise used for input/output (I/O) signal interconnects for coupling I/O signals to the IC die. The EMI shield is electrically coupled to a ground node of the IC die to provide an effective Faraday EMI shield to block or attenuate unwanted EM noise propagated from the IC die outside the IC. By using the unused areas in the fan-out area forming the vias of the EMI shield, the EMI shield can be formed for the IC die as part of the fabrication process of the IC die. Further, additional area and cost can be avoided providing EMI shields and/or compartmentalized metal structures in the IC package to EM shield the IC die.

In other exemplary aspects, the EMI shield can include one or more via array structures formed in fan-out areas that are unused for I/O signal interconnects on one or more sides adjacent to the IC die. For example, it may be desired to form a via array structure in un-used areas of the fan-out areas on each side of the IC die to form a fully side-enclosed EMI shield. The IC can also include an optional conductive layer on the backside of the IC die electrically coupled to a via array structure(s) to form part of the EMI shield.

In other exemplary aspects, a fabrication process is provided to fabricate the FOWLP IC. In exemplary aspects, the vias of a via array structure are formed in a reconstituted carrier wafer before IC dies are mounted to the reconstituted carrier wafer and overmolded to form an EMI shield. The vias of the via array structure can be formed in patterned openings in a dielectric layer of the reconstituted carrier wafer that are aligned in what will be an unused areas in the fan-out area when the reconstituted IC dies are placed on the reconstituted carrier wafer. A metallization layer(s) is formed on the active side of the placed IC dies on the reconstituted carrier wafer. A ground node or layer of the metallization layer(s) of each reconstituted IC die is formed in electrical contact with its respective via array structure such that the via array structure will form an EMI shield for its respective IC die.

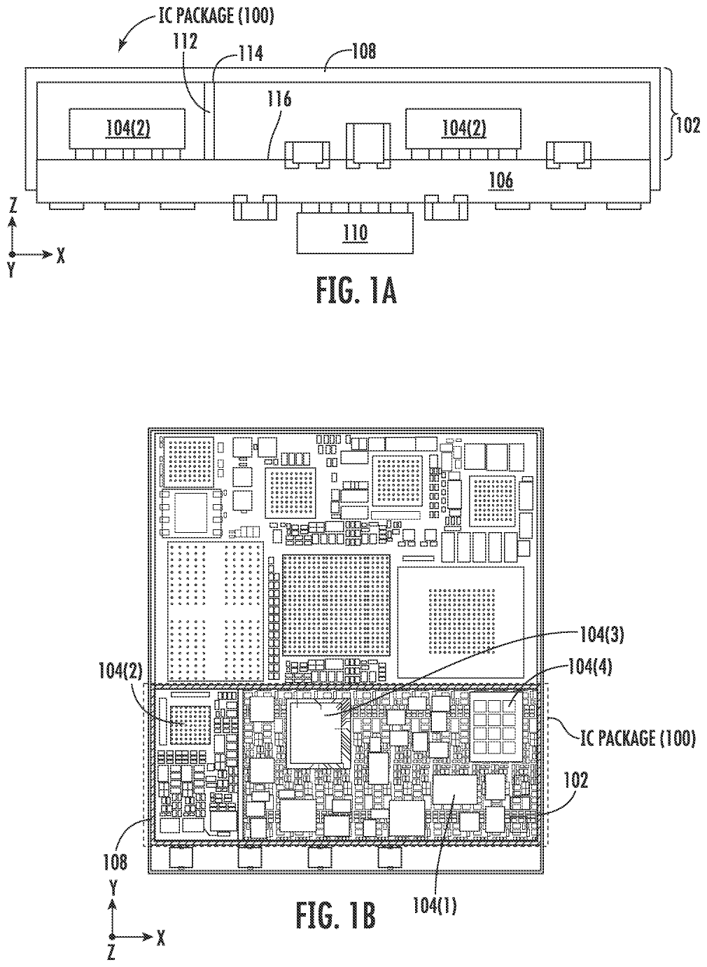

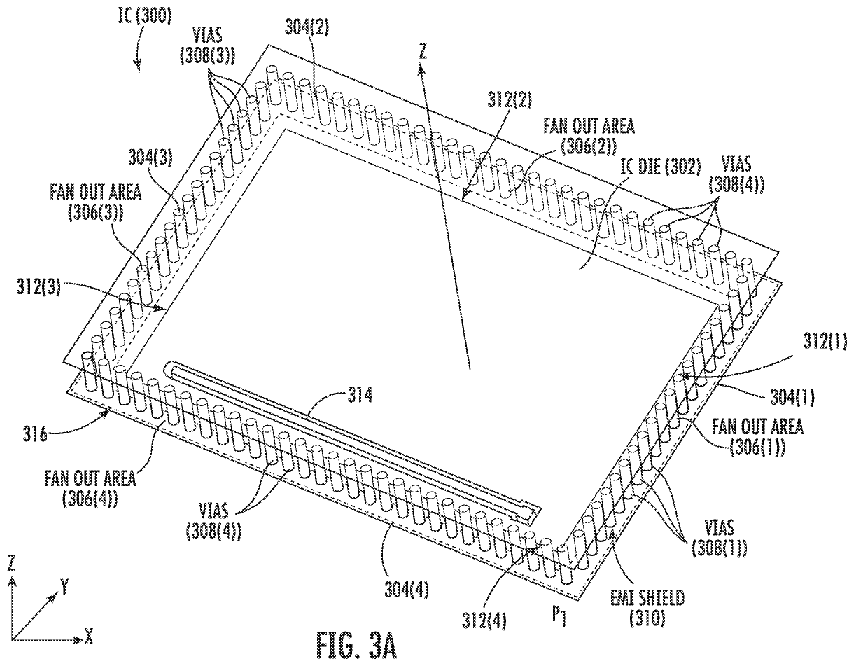

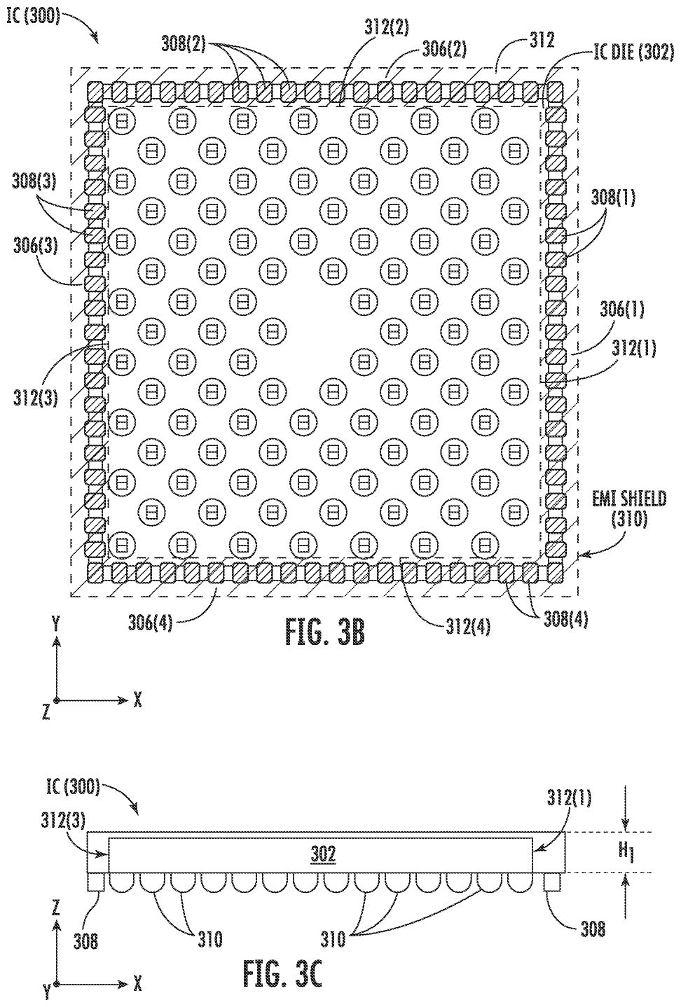

Before discussing examples of a FOWLP IC employing an EMI shield in an unused fan-out area for EMI shielding starting at FIG. 3A, an example of an IC package that includes a die module with a plurality of IC chips mounted on a package substrate with EMI shielding compartmentalized by metal cans for the individual IC chips is first described with respect to FIGS. 1A and 1B.

In this regard, FIGS. 1A and 1B are side and top views, respectively, of an IC package 100 that includes a die module 102 with a plurality of IC chips 104(1)-104(5) mounted on a package substrate 106. An EMI shield 108 is provided and disposed over the die module 102 to provide EMI shielding of the IC chips 104(1)-104(5). The EMI shield 108 can be a thin metal enclosure that is made from a metal material, such as tin or copper, or alloys thereof, for example. For example, without EMI shielding, EM noise emitted from the IC chips 104(1)-104(5) may interfere with other circuit routing and circuits in the IC package 100, such as IC chip 110. For example, IC chip 110 may be a radio-frequency (RF) IC that includes RF circuits that are sensitive to EM noise. While the EMI shield 108 may mitigate or block EM noise emitted from the IC chips 104(1)-104(5) to the IC chip 110 for example, the EMI shield 108 does not mitigate or block EM noise between the IC chips 104(1)-104(5) themselves. To address this, as shown in FIG. 1A, the die module 102 also includes a metal structure 112 to provide EMI isolation between IC chips 104(1), 104(2). The metal structure 112 is disposed inside the EMI shield 108 and extends from an inside surface 114 of the EMI shield 108 to a top surface 116 of the package substrate 106. In this manner, the IC chips 104(1), 104(2) are compartmentalized inside the die module 102 from an EM noise perspective to reduce or avoid propagation of EM noise emission from one IC chip 104(1) to the other IC chip 104(2), and vice versa. More metal structures 112 can be provided if additional EM compartmentalization is desired between the other IC chips 104(3), 104(4). Regardless, the metal structures 112 add cost to the die module 102 and increase the complexity of fabrication processes.

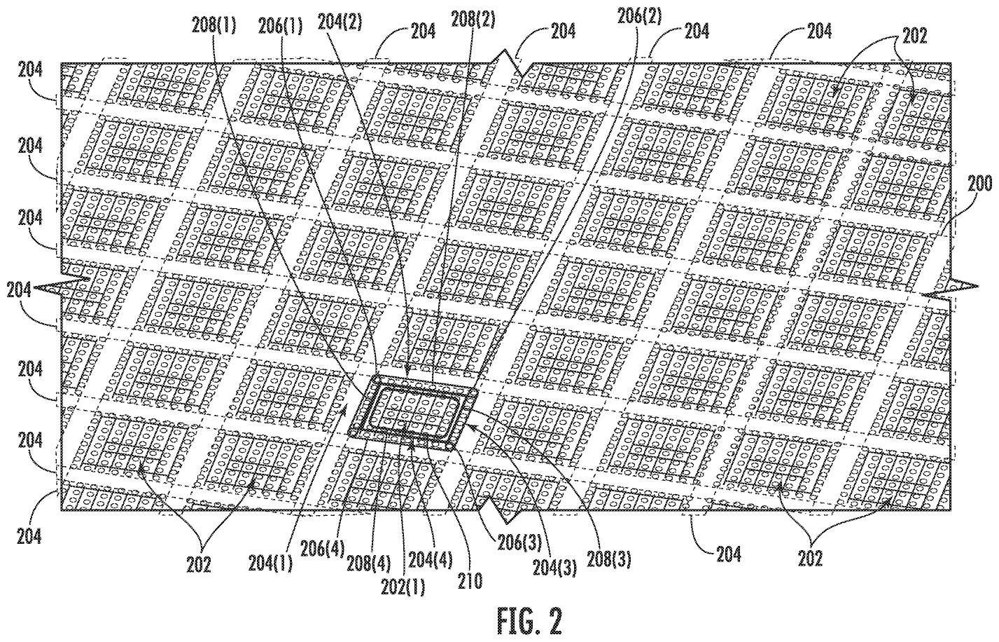

IC dies, like those that are included in the IC chips 104(1)-104(3) in the IC package 100 in FIGS. 1A and 1B, can be packaged according to a FOWLP process as an enhancement of standard wafer-level packaging (WLP) solutions. FIG. 2 is a perspective view of an exemplary reconstituted carrier wafer 200 formed from a FOWLP process. The reconstituted carrier wafer 200 includes a plurality of IC dies 202 that can be singulated (i.e., diced) and packaged in an IC package. In the FOWLP process, the IC dies 202 are first fabricated on a semiconductor wafer that is diced to singulate the IC dies 202. Then, the IC dies 202 are repositioned on the reconstituted carrier wafer 200 with space provided between the IC dies 202 to provide fan-out areas 204 on the reconstituted carrier wafer 200 and around and adjacent to the outer sides each IC die 202. The fan-out areas 204 provide areas where fan-out interconnects 206 can be formed in a metallization structure, such as redistribution layers (RDLs), to provide for additional die interconnects in the fan-out area 204. The additional die interconnects allow more interconnections to be provided to the IC die 202 when repackaged in an IC package. For instance, taking IC die 202(1) as an example, fan-out areas 204(1)-204(4) are provided adjacent to the respective outer sides 208(1)-208(4) of the IC die 202(1) on the reconstituted carrier wafer 200. Fan-out interconnects 206(1)-206(4) are provided in the respective fan-out areas 204(1)-204(4) on the reconstituted carrier wafer 200. The fan-out interconnects 206(1)-206(4) are electrically coupled to the IC die 202(1) to provide additional die interconnections to the IC die 202(1). Other die interconnects are located on the wafer 200 directly above the IC die 202(1) within the footprint 210 of the IC die 202(1) in the Z-axis direction and that can be interconnected to the IC die 202(1) for I/O signal and other signal interconnections.

FIGS. 3A-3C are perspective, bottom, and side views, respectively, of an exemplary IC 300 that includes an IC die 302 with fan-out interconnects 304(1)-304(4) in respective fan-out areas 306(1)-306(4) adjacent to and electrically coupled to the IC die 302 for providing external connections to the IC die 302. The IC die 302 is disposed generally in a horizontal plane P₁ in the X-axis and Y-axis directions. As shown in FIG. 3C, the IC die 302 does have a thickness or height H₁ in the Z-axis direction. The IC 300 could have been fabricated by a FOWLP process as an example. As discussed in more detail below, the IC 300 includes vias 308(1)-308(4) that are formed in the fan-out areas 306(1)-306(4) of the IC 300 adjacent to the IC die 302 to provide an EMI shield 310 for the IC die 302. The EMI shield 310 is electrically coupled to a ground of the IC die 302 to form an EMI shield for the IC die 302. The EMI shield 310 is formed from the vias 308(1)-308(4) that are formed in unused areas in fan-out areas 306(1)-306(4) that are not otherwise used for I/O signal interconnects for coupling I/O signals to the IC die 302. The fan-out areas 306(1)-306(4) are located adjacent to respective outer sides 312(1)-312(4) of the IC die 302.

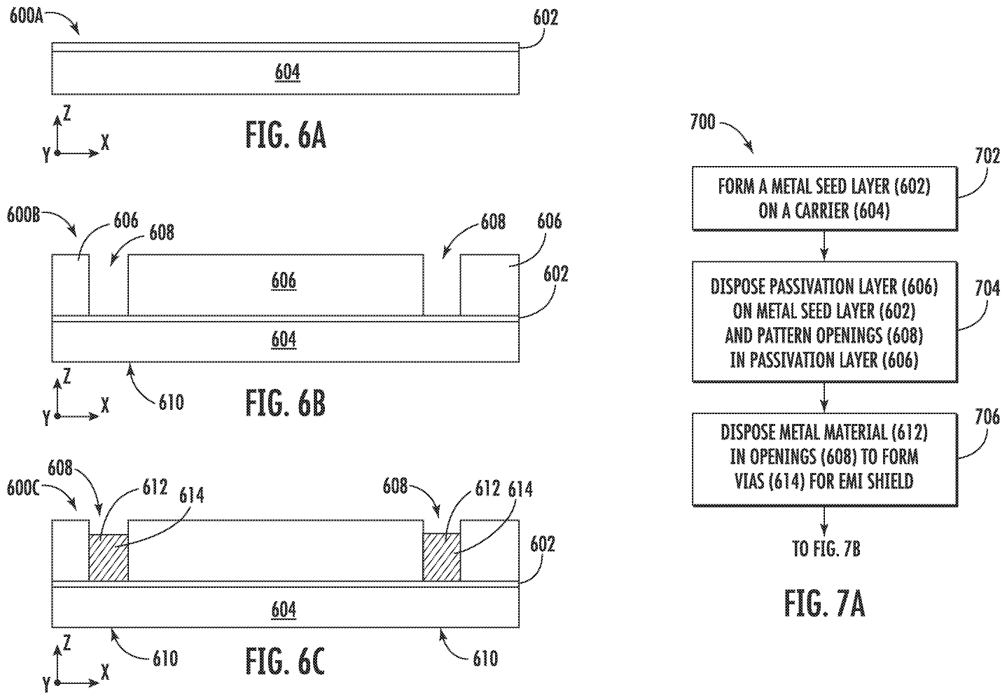

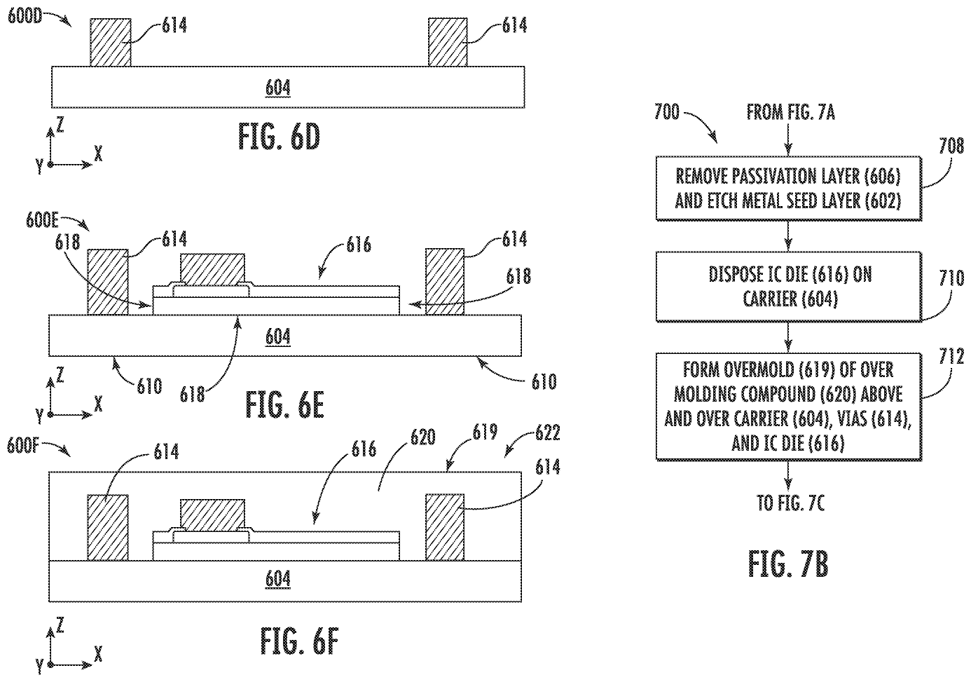

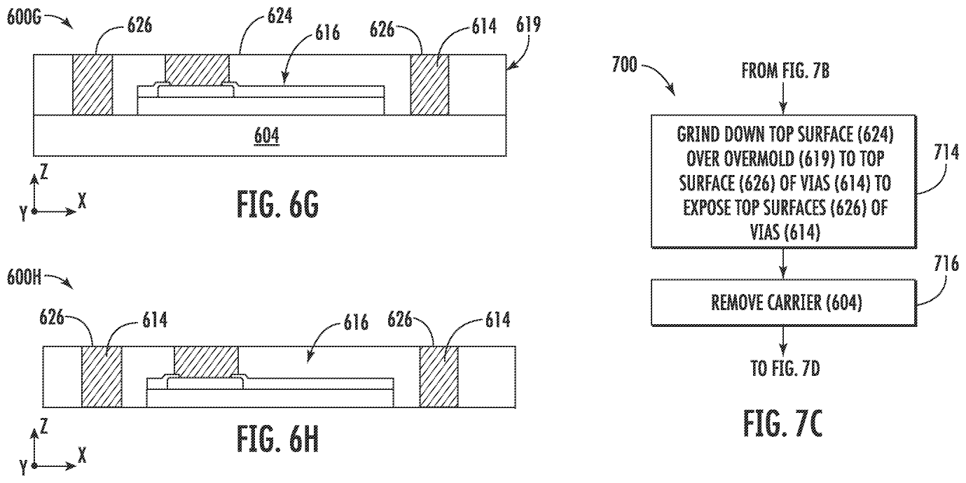

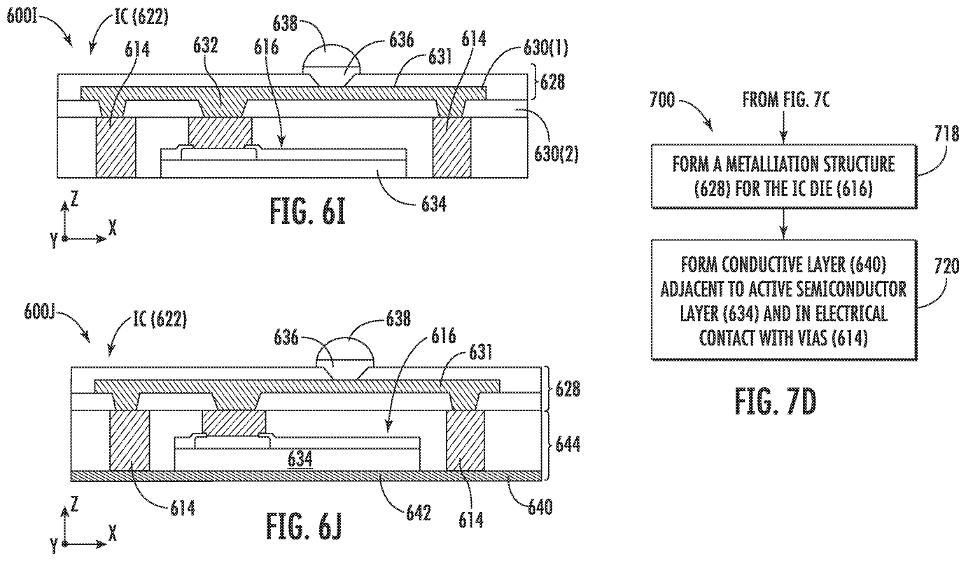

As shown in FIG. 3A, the EMI shield 310 is electrically coupled to a ground node 314 of the IC die 302 to provide an effective Faraday EMI shield to block or attenuate unwanted EM noise propagated from the IC die 302 outside the IC 300. By using the unused areas in the fan-out areas 306(1)-306(4) forming the vias 308(1)-308(4) of the EMI shield 310, the EMI shield 310 can be formed for the IC die 302 as part of the fabrication process of the IC die 302. For example, as discussed in more detail below starting at FIG. 6A, the vias 308(1)-308(4) of the EMI shield 310 can be formed as part of a FOWLP process of fabricating the IC 300. Thus, additional area and cost can be avoided in providing EMI shields and/or compartmentalized metal structures in an IC package that includes the IC 300 to EM shield the IC die 302.

With continuing reference to FIG. 3A-3C, the IC die 302 includes a plurality of die sides 312(1)-312(4). The fan-out areas 306(1)-306(4) are each disposed adjacent in the horizontal plane P₁ to the respective die sides 312(1)-312(4). The number of die sides 312(1)-312(4) is four (4) in this example, because the IC die 302 is a rectangular-shaped die. Note that some areas in the fan-out areas 306(1)-306(4) may be used for providing I/O signal fan-out interconnects that are used for routing I/O signals to the IC die 302. The areas of the fan-out areas 306(1)-306(4) that are used for I/O signal fan-out interconnects are deemed “used” areas in the fan-out areas 306(1)-306(4). The areas of the fan-out areas 306(1)-306(4) that are not used for I/O signal fan-out interconnects are deemed “unused” areas in the fan-out areas 306(1)-306(4) in which the vias 308(1)-308(4) can be formed to form a part of the EMI shield 310. For example, with reference to FIG. 3A, I/O signal fan-out interconnects 316 that are disposed adjacent to a die side 312(1)-312(4) of the IC die 302 can be provided in the IC 300 for making I/O signal connections to the IC die 302.

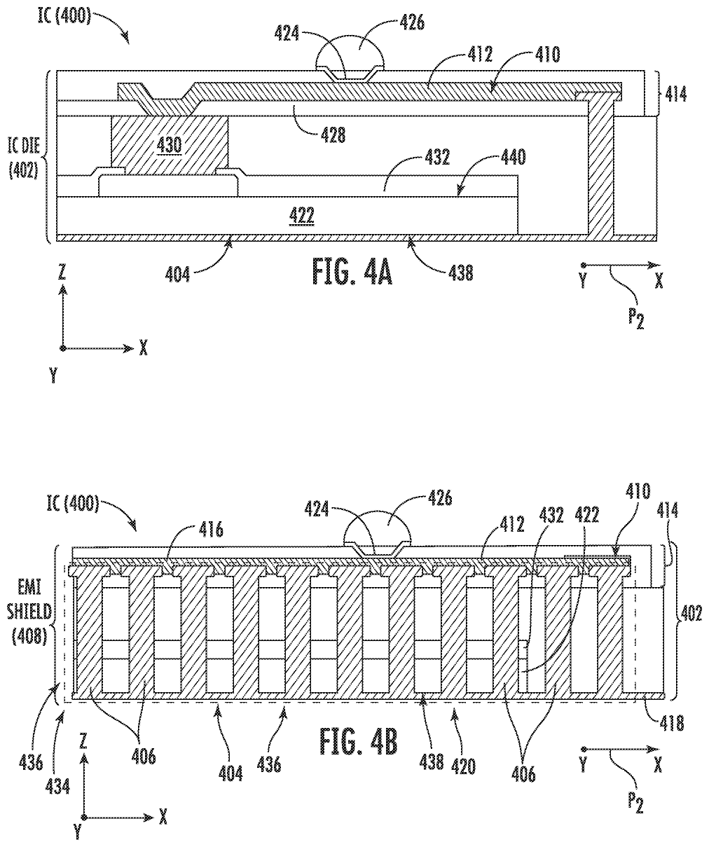

FIG. 4A is a side view of an exemplary IC 400 that includes an IC die 402 and that does not include vias formed in a fan-out area 404 of the IC die 402 to form an EMI shield. However, vias 406 can be formed in a fan-out area 404 of the IC die 402, like shown in FIG. 4B, to form an EMI shield 408. The IC die 402 in FIGS. 4A and 4B could be the IC die 302 in FIGS. 3A-3C. The IC 400 includes the IC die 402 that can be formed by a FOWLP process as described in more detail below. The IC die 402 in FIGS. 4A and 4B has been fabricated and singulated to be included in the IC 400. As discussed in more detail below, the IC 400 in FIG. 4B is shown with an EMI shield 408 that includes the vias 406 formed in unused areas in the fan-out area 404 adjacent to the IC die 402 that are not otherwise used for I/O signal interconnects for coupling I/O signals to the IC die 402. The EMI shield 408 is electrically coupled to a ground node 410 of the IC die 402 formed as a metal line 412 in a redistribution layer in a metallization structure 414 of the IC 400 in this example to provide an effective Faraday EMI shield to block or attenuate unwanted EM noise propagated from the IC die 402 outside the IC 400. By using the unused areas in the fan-out area 404 forming the vias 406 of the EMI shield 408, the EMI shield 408 can be formed for the IC die 402 as part of the fabrication process of the IC die 402. Further, additional area and cost can be avoided in providing EMI shields and/or compartmentalized metal structures in an IC package that includes the IC 400 to EM shield the IC die 402.

In this example and as discussed in more detail below, the EMI shield 408 of the IC 400 is formed by the vias 406 formed as a via array structure 416. As shown in FIG. 4B, the IC 400 can also include an optional conductive layer 418 on the backside 420 of the IC die 402 electrically coupled to the via array structure 416 to form part of the EMI shield 408.

With reference to FIGS. 4A and 4B, the IC die 402 includes an active semiconductor layer 422 that is disposed in a horizontal plane P₂ in the X-axis and Y-axis directions. Semiconductor devices can be formed in the active semiconductor layer 422. For example, the active semiconductive layer 422 may be include a Silicon semiconductor material that is doped to form P-N junctions for forming semiconductor devices, such as field-effect transistors (FETs). The IC die 402 also includes the metallization structure 414 that includes a plurality of die interconnects 424 electrically coupled to the active semiconductor layer 422 to provide external electrical connections to the semiconductor devices formed in the active semiconductor layer 422. In this example, there is one die interconnect 424 shown in which an external interconnect 426 (e.g., a solder ball) is coupled to provide an electrical interface to the die interconnect 424. The die interconnect 424 is coupled to the metal line 412 in this example that forms the ground node 410, which is then electrically connected through other metal layers 428 in the metallization structure 414 to the active semiconductor layer 422. In this example, a metal pillar 430, which serves as a ground conductive pillar, extends from the active semiconductor layer 422 through a passivation layer 432 and to the metal line 412 to form a connection between the active semiconductor layer 422 and the metal line 412. The metal pillar 430 may be made from a copper material as an example.

With continuing reference to FIG. 4B, the fan-out area 404 of the IC 400 can also include I/O signal fan-out interconnects 434 that are disposed adjacent to a die side 436 of the IC die 402 that are used for making I/O signal connections to the IC die 402. The vias 406 forming the EMI shield 408 are not electrically coupled to any I/O signal fan-out interconnects 434. The vias 406 that form the EMI shield 408 can be disposed in one or more die sides 436 of the IC die 402. For example, the vias 406 that form the EMI shield 408 can be disposed in a fan-out area 404 in only one side 436 of the IC die 402 or multiple sides 436 of the IC die 402. In the example in FIG. 4B, the IC 400 also includes a conductive layer 418 on the backside 420 of the IC die 402 electrically coupled to the via array structure 416 to form part of the EMI shield 408. This can improve the EM shielding provided by the EMI shield 408. The conductive layer 418 is adjacent to an inactive surface 438 of the active semiconductor layer 422. The passivation layer 432 of the IC die 402 is disposed adjacent to an active surface 440 of the active semiconductor layer 422.

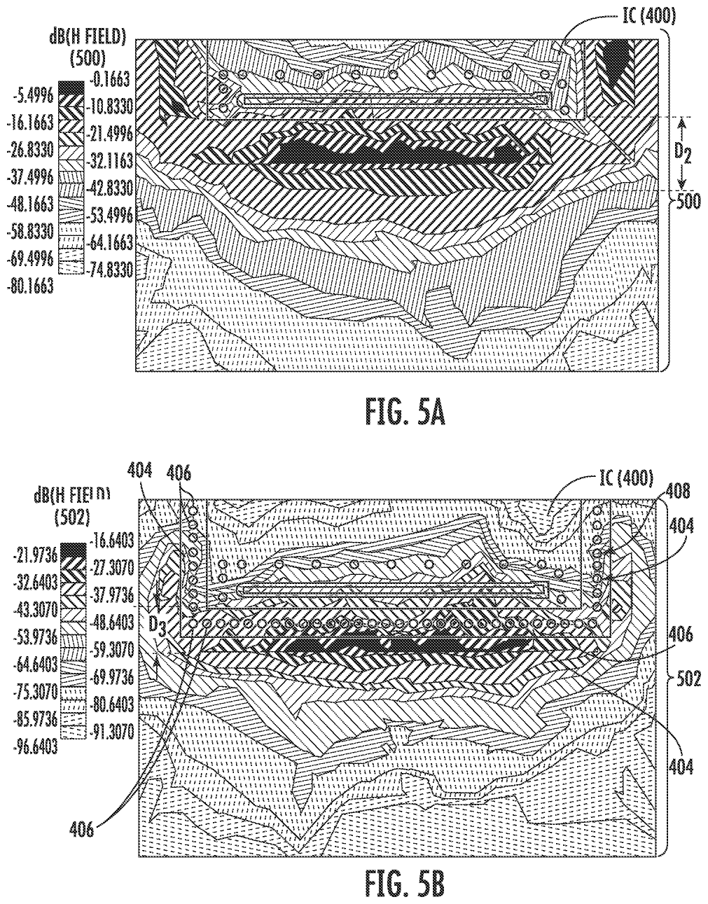

FIG. 5A is a diagram illustrating exemplary H-field emission 500 by the IC die 402 in the IC 400 in FIG. 4A that does not include vias 406 formed in a fan-out area 404 of the IC 400. FIG. 5B is a diagram illustrating exemplary H-field emission 502 by the IC die 402 in the IC 400 when the vias 406 are formed in the fan-out area 404 of the IC 400. As shown in FIG. 5A, the H-field emission 500 extends a greater distance D₂ away from the IC 400 than the H-field emission 502 extends as distance D₃ as shown in FIG. 5B. The EMI shield 408 in the IC die 402 in FIGS. 4B and 5B is providing a greater EM shield than provided in the IC die 402 in FIGS. 4A and 5A.

FIGS. 6A-6J illustrate exemplary fabrication stages of an exemplary process of fabricating an IC according to a FOWLP process that includes vias formed in a fan-out area of the IC to form an EMI shield for the IC die. For example, the fabricated IC could be the ICs 300, 400 in FIGS. 3A-3C and 4B for example. FIGS. 7A-7D area flowchart illustrating an exemplary process 700 of fabricating the IC according to the exemplary fabrication stages in FIGS. 6A-6J. The fabrication stages in FIGS. 6A-6J and the process steps in the exemplary process 700 in FIGS. 7A-7D will be discussed in conjunction with each other below.

FIG. 6A illustrates an exemplary fabrication stage 600A to prepare an EMI shield to be formed in a fan-out area of an IC. In this regard, as shown in FIG. 6A, the fabrication stage 600A includes forming a metal seed layer 602 disposed on a carrier 604 (block 702 in FIG. 7A). For example, the metal seed layer 602 can be a copper seed layer. As shown in the fabrication stage 600B in FIG. 6B, to form the vias in a fan-out area of the IC for forming an EMI shield, a passivation layer 606 is then disposed on the metal seed layer 602 (block 704 in FIG. 7A). The passivation layer 606 is then patterned and one or more openings 608 are formed in the passivation layer 606 such that each opening 608 will be disposed in a fan-out area 610 for an IC when formed (704 in FIG. 7A). Then, as shown in the fabrication stage 600C in FIG. 6C, a metal material 612 is disposed into the openings 608 to form the vias 614 that will form part of the EMI shield for the IC (block 706 in FIG. 7A).

As shown in the fabrication stage 600D in FIG. 6D, a next step in the fabrication process 700 is to then remove the passivation layer 606 and the metal seed layer 602 that is disposed outside of the vias 614 (block 708 in FIG. 7B). For example, the passivation layer 602 and the metal seed layer 602 that is disposed outside of the vias 614 can be removed by a photoresist stripping and seed layer etching process. As shown in the fabrication stage 600E in FIG. 6E, a next step is to place a reconstituted IC die 616 on the carrier 604 and between the vias 614 in the fan-out areas 610 (block 710 in FIG. 7B). For example, the IC die 616 can be the IC die 302, 402 in FIGS. 3A-3C and/or 4B. The IC die 616 is disposed on the carrier 604 such that the one or more fan-out areas 610 are each adjacent to a different die side 618 of the IC die 616. As shown in the fabrication stage 600F in FIG. 6F a next step is to form an overmold 619 comprising an overmolding compound 620 over and above the carrier 604, the vias 614, and the IC die 616 as part of the IC 622 (block 712 in FIG. 7B).

As shown in the fabrication stage 600G in FIG. 6G, a next fabrication step is to grind down a top surface 624 of the overmold 619 to a top surface 626 of the vias 614 to expose the top surface 626 of the vias 614 (block 714 in FIG. 7C). This is to prepare for the metallization structure to be formed in electrical contact with the IC die 616. As shown in the fabrication stage 600H in FIG. 6H, the carrier 604 is removed (block 716 in FIG. 7C). As shown in the fabrication stage 600I in FIG. 6I, a metallization structure 628 is formed in electrical contact with the IC die 616 (block 718 in FIG. 7D). The metallization structure 628 is formed by forming a first metallization layer 630(1) comprising a ground metal line 631 electrically coupled to the vias 614. A second metallization layer 630(2) can be formed that includes a die interconnect 632 electrically coupled to an active semiconductor layer 634 of the IC die 616. A die interconnect 636 can be formed in contact with the metallization layer 630(1) to provide an external interface to the IC die 616 and/or the ground node formed by the ground metal line 631. An external interconnect 638 (e.g., a solder ball) can be formed in contact with the die interconnect 636. As shown in the fabrication stage 600J in FIG. 6J, an optional conductive layer 640 can be formed adjacent to an inactive surface 642 of the active semiconductor layer 634 and electrically coupled to the vias 614 to also form part of an EMI shield 644 formed by the vias 614 (block 720 in FIG. 7D).

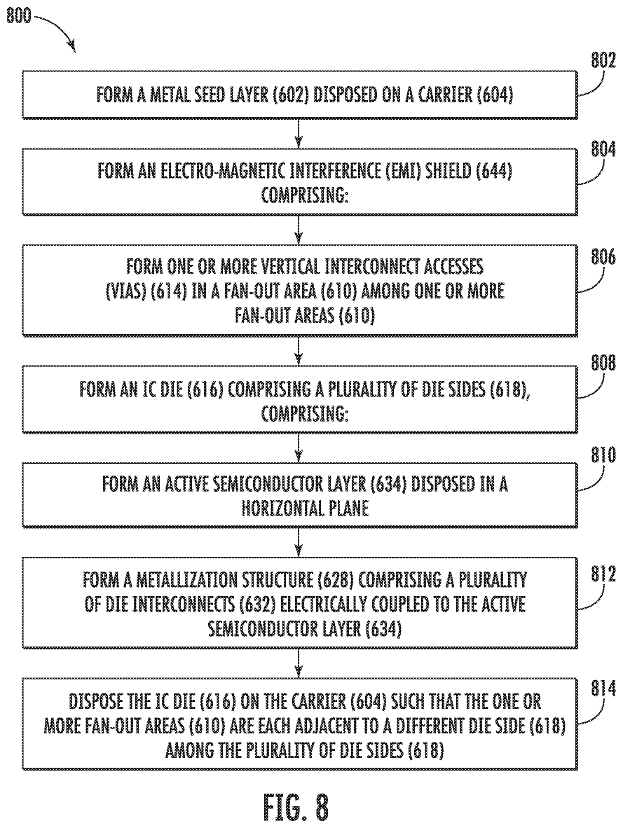

FIG. 8 is a flowchart illustrating another exemplary process 800 of fabricating an IC that includes vias formed in a fan-out area of the IC that is otherwise unused for fan-out I/O signal interconnects to form an EMI shield for the IC die. The IC fabricated according to the process 800 can include the ICs 300, 400 in FIGS. 3A-3C and 4B as an example. The process 800 in FIG. 8 will be discussed in reference to the elements in the fabrication stages 600A-600J in FIGS. 6A-6J. In this regard, an exemplary step in the process 800 is to form the metal seed layer 602 disposed on the carrier 604 (block 802 in FIG. 8). Another exemplary step in the process 800 is to form the EMI shield 644 (block 804 in FIG. 8). The EMI shield 644 can be formed by forming the one or more vias 614 in the fan-out area 610 among the one or more fan-out areas 610 (block 806 in FIG. 8). The process 800 can also include the step of forming the IC die 616 comprising the plurality of die sides 618 (block 808 in FIG. 8). Forming the IC die 616 can include forming an active semiconductor layer 634 disposed in a horizontal plane (block 810 in FIG. 8), and forming the metallization structure 628 comprising a plurality of die interconnects 632 electrically coupled to the active semiconductor layer 634 (block 812 in FIG. 8). The process 800 can also include disposing the IC die 616 on the carrier 604 such that the one or more fan-out areas 610 are each adjacent to a different die side 618 among the plurality of die sides 618 (block 814 in FIG. 8).

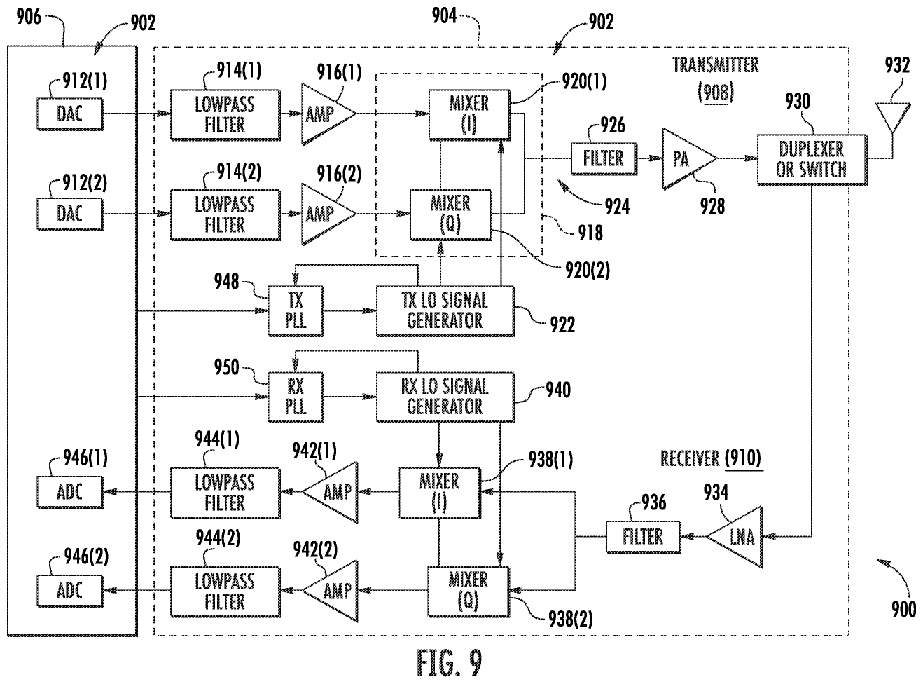

FIG. 9 illustrates an exemplary wireless communications device 900 that includes RF components formed from one or more ICs 902, wherein any of the ICs 902 include an IC die and include vias formed in a fan-out area of the IC that is otherwise unused for fan-out I/O signal interconnects to form an EMI shield for an IC die, including, but not limited to, the FOWLP ICs in FIGS. 3A-3C and 4B, and according to any of the fabrication processes in FIGS. 6A-8. As shown in FIG. 9, the wireless communications device 900 includes a transceiver 904 and a data processor 906. The data processor 906 may include a memory to store data and program codes. The transceiver 904 includes a transmitter 908 and a receiver 910 that support bi-directional communications. In general, the wireless communications device 900 may include any number of transmitters 908 and/or receivers 910 for any number of communication systems and frequency bands. All or a portion of the transceiver 904 may be implemented on one or more analog ICs, RFICs, mixed-signal ICs, etc.

The transmitter 908 or the receiver 910 may be implemented with a super-heterodyne architecture or a direct-conversion architecture. In the super-heterodyne architecture, a signal is frequency-converted between RF and baseband in multiple stages, e.g., from RF to an intermediate frequency (IF) in one stage, and then from IF to baseband in another stage. In the direct-conversion architecture, a signal is frequency-converted between RF and baseband in one stage. The super-heterodyne and direct-conversion architectures may use different circuit blocks and/or have different requirements. In the wireless communications device 900 in FIG. 9, the transmitter 908 and the receiver 910 are implemented with the direct-conversion architecture.

In the transmit path, the data processor 906 processes data to be transmitted and provides I and Q analog output signals to the transmitter 908. In the exemplary wireless communications device 900, the data processor 906 includes digital-to-analog converters (DACs) 912(1), 912(2) for converting digital signals generated by the data processor 906 into the I and Q analog output signals, e.g., I and Q output currents, for further processing.

Within the transmitter 908, lowpass filters 914(1), 914(2) filter the I and Q analog output signals, respectively, to remove undesired signals caused by the prior digital-to-analog conversion. Amplifiers (AMPs) 916(1), 916(2) amplify the signals from the lowpass filters 914(1), 914(2), respectively, and provide I and Q baseband signals. An upconverter 918 upconverts the I and Q baseband signals with I and Q transmit (TX) local oscillator (LO) signals from a TX LO signal generator 922 through mixers 920(1), 920(2) to provide an upconverted signal 924. A filter 926 filters the upconverted signal 924 to remove undesired signals caused by the frequency upconversion as well as noise in a receive frequency band. A power amplifier (PA) 928 amplifies the upconverted signal 924 from the filter 926 to obtain the desired output power level and provides a transmit RF signal. The transmit RF signal is routed through a duplexer or switch 930 and transmitted via an antenna 932.

In the receive path, the antenna 932 receives signals transmitted by base stations and provides a received RF signal, which is routed through the duplexer or switch 930 and provided to a low noise amplifier (LNA) 934. The duplexer or switch 930 is designed to operate with a specific receive (RX)-to-TX duplexer frequency separation, such that RX signals are isolated from TX signals. The received RF signal is amplified by the LNA 934 and filtered by a filter 936 to obtain a desired RF input signal. Downconversion mixers 938(1), 938(2) mix the output of the filter 936 with I and Q RX LO signals (i.e., LO_I and LO_Q) from an RX LO signal generator 940 to generate I and Q baseband signals. The I and Q baseband signals are amplified by AMIPs 942(1), 942(2) and further filtered by lowpass filters 944(1), 944(2) to obtain I and Q analog input signals, which are provided to the data processor 906. In this example, the data processor 906 includes analog-to-digital converters (ADCs) 946(1), 946(2) for converting the analog input signals into digital signals to be further processed by the data processor 906.

In the wireless communications device 900 of FIG. 9, the TX LO signal generator 922 generates the I and Q TX LO signals used for frequency upconversion, while the RX LO signal generator 940 generates the I and Q RX LO signals used for frequency downconversion. Each LO signal is a periodic signal with a particular fundamental frequency. A TX phase-locked loop (PLL) circuit 948 receives timing information from the data processor 906 and generates a control signal used to adjust the frequency and/or phase of the TX LO signals from the TX LO signal generator 922. Similarly, an RX PLL circuit 950 receives timing information from the data processor 906 and generates a control signal used to adjust the frequency and/or phase of the RX LO signals from the RX LO signal generator 940.

ICs that include an IC die and include vias formed in a fan-out area of the IC that is otherwise unused for fan-out I/O signal interconnects to form an EMI shield for an IC die, including, but not limited to, the FOWLP ICs in FIGS. 3A-3C and 4B, and according to any of the fabrication processes in FIGS. 6A-8, may be provided in or integrated into any processor-based device. Examples, without limitation, include a set top box, an entertainment unit, a navigation device, a communications device, a fixed location data unit, a mobile location data unit, a global positioning system (GPS) device, a mobile phone, a cellular phone, a smart phone, a session initiation protocol (SIP) phone, a tablet, a phablet, a server, a computer, a portable computer, a mobile computing device, a wearable computing device (e.g., a smart watch, a health or fitness tracker, eyewear, etc.), a desktop computer, a personal digital assistant (PDA), a monitor, a computer monitor, a television, a tuner, a radio, a satellite radio, a music player, a digital music player, a portable music player, a digital video player, a video player, a digital video disc (DVD) player, a portable digital video player, an automobile, a vehicle component, avionics systems, a drone, and a multicopter. The wireless communications device 900 may also include or be provided in any of the above-referenced devices, as examples.

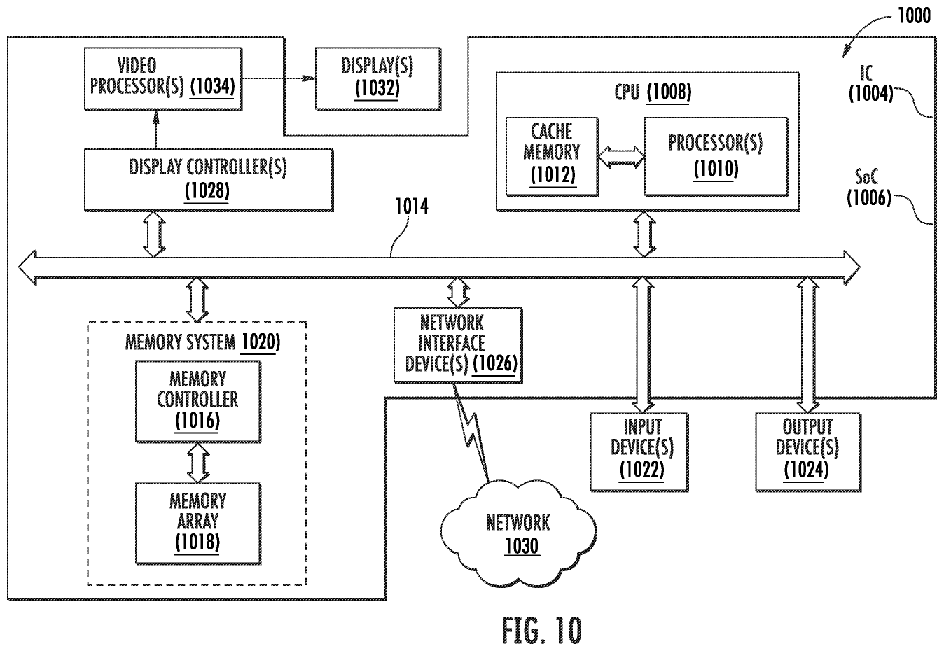

In this regard, FIG. 10 illustrates an example of a processor-based system 1000 that includes an IC 1004 that includes an IC die and vias formed in a fan-out area of the IC that is otherwise unused for fan-out I/O signal interconnects to form an EMI shield for an IC die, including, but not limited to, the FOWLP ICs in FIGS. 3A-3C and 4B, and according to any of the fabrication processes in FIGS. 6A-8, and according to any aspects disclosed herein. In this example, the processor-based system 1000 may be formed as an IC 1004 in an IC package and as a system-on-a-chip (SoC) 1006. The processor-based system 1000 includes a CPU 1008 that includes one or more processors 1010, which may also be referred to as CPU cores or processor cores. The CPU 1008 may have cache memory 1012 coupled to the CPU 1008 for rapid access to temporarily stored data. The CPU 1008 is coupled to a system bus 1014 and can intercouple master and slave devices included in the processor-based system 1000. As is well known, the CPU 1008 communicates with these other devices by exchanging address, control, and data information over the system bus 1014. For example, the CPU 1008 can communicate bus transaction requests to a memory controller 1016 as an example of a slave device. Although not illustrated in FIG. 10, multiple system buses 1014 could be provided, wherein each system bus 1014 constitutes a different fabric.

Other master and slave devices can be connected to the system bus 1014. As illustrated in FIG. 10, these devices can include a memory system 1020 that includes the memory controller 1016 and a memory array(s) 1018, one or more input devices 1022, one or more output devices 1024, one or more network interface devices 1026, and one or more display controllers 1028, as examples. Each of the memory system 1020, the one or more input devices 1022, the one or more output devices 1024, the one or more network interface devices 1026, and the one or more display controllers 1028 can be provided in the same or different IC packages. The input device(s) 1022 can include any type of input device, including, but not limited to, input keys, switches, voice processors, etc. The output device(s) 1024 can include any type of output device, including, but not limited to, audio, video, other visual indicators, etc. The network interface device(s) 1026 can be any device configured to allow exchange of data to and from a network 1030. The network 1030 can be any type of network, including, but not limited to, a wired or wireless network, a private or public network, a local area network (LAN), a wireless local area network (WLAN), a wide area network (WAN), a BLUETOOTH™ network, and the Internet. The network interface device(s) 1026 can be configured to support any type of communications protocol desired.

The CPU 1008 may also be configured to access the display controller(s) 1028 over the system bus 1014 to control information sent to one or more displays 1032. The display controller(s) 1028 sends information to the display(s) 1032 to be displayed via one or more video processors 1034, which process the information to be displayed into a format suitable for the display(s) 1032. The display controller(s) 1028 and video processor(s) 1034 can be included as ICs 1004 in the same or different IC packages, and in the same or different IC package containing the CPU 1008 as an example. The display(s) 1032 can include any type of display, including, but not limited to, a cathode ray tube (CRT), a liquid crystal display (LCD), a plasma display, a light emitting diode (LED) display, etc.

Those of skill in the art will further appreciate that the various illustrative logical blocks, modules, circuits, and algorithms described in connection with the aspects disclosed herein may be implemented as electronic hardware, instructions stored in memory or in another computer readable medium and executed by a processor or other processing device, or combinations of both. The master and slave devices described herein may be employed in any circuit, hardware component, IC, or IC chip, as examples. Memory disclosed herein may be any type and size of memory and may be configured to store any type of information desired. To clearly illustrate this interchangeability, various illustrative components, blocks, modules, circuits, and steps have been described above generally in terms of their functionality. How such functionality is implemented depends upon the particular application, design choices, and/or design constraints imposed on the overall system. Skilled artisans may implement the described functionality in varying ways for each particular application, but such implementation decisions should not be interpreted as causing a departure from the scope of the present disclosure.

The various illustrative logical blocks, modules, and circuits described in connection with the aspects disclosed herein may be implemented or performed with a processor, a Digital Signal Processor (DSP), an Application Specific Integrated Circuit (ASIC), a Field Programmable Gate Array (FPGA) or other programmable logic device, discrete gate or transistor logic, discrete hardware components, or any combination thereof designed to perform the functions described herein. A processor may be a microprocessor, but in the alternative, the processor may be any conventional processor, controller, microcontroller, or state machine. A processor may also be implemented as a combination of computing devices (e.g., a combination of a DSP and a microprocessor, a plurality of microprocessors, one or more microprocessors in conjunction with a DSP core, or any other such configuration).

The aspects disclosed herein may be embodied in hardware and in instructions that are stored in hardware, and may reside, for example, in Random Access Memory (RAM), flash memory, Read Only Memory (ROM), Electrically Programmable ROM (EPROM), Electrically Erasable Programmable ROM (EEPROM), registers, a hard disk, a removable disk, a CD-ROM, or any other form of computer readable medium known in the art. An exemplary storage medium is coupled to the processor such that the processor can read information from, and write information to, the storage medium. In the alternative, the storage medium may be integral to the processor. The processor and the storage medium may reside in an ASIC. The ASIC may reside in a remote station. In the alternative, the processor and the storage medium may reside as discrete components in a remote station, base station, or server.

It is also noted that the operational steps described in any of the exemplary aspects herein are described to provide examples and discussion. The operations described may be performed in numerous different sequences other than the illustrated sequences. Furthermore, operations described in a single operational step may actually be performed in a number of different steps. Additionally, one or more operational steps discussed in the exemplary aspects may be combined. It is to be understood that the operational steps illustrated in the flowchart diagrams may be subject to numerous different modifications as will be readily apparent to one of skill in the art. Those of skill in the art will also understand that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

The previous description of the disclosure is provided to enable any person skilled in the art to make or use the disclosure. Various modifications to the disclosure will be readily apparent to those skilled in the art, and the generic principles defined herein may be applied to other variations. Thus, the disclosure is not intended to be limited to the examples and designs described herein, but is to be accorded the widest scope consistent with the principles and novel features disclosed herein.

Implementation examples are also described in the following numbered aspects:

1. An integrated circuit (IC), comprising:
an IC die comprising a plurality of die sides, the IC die comprising:
   an active semiconductor layer disposed in a horizontal plane; and
   a metallization structure comprising a plurality of die interconnects electrically coupled to the active semiconductor layer;
one or more input/output (I/O) signal fan-out interconnects each disposed in a fan-out area among one or more fan-out areas each adjacent to a different die side among the plurality of die sides of the IC die in the horizontal plane, the one or more I/O signal fan-out interconnects electrically coupled to one or more die interconnects among the plurality of die interconnects; and
an electro-magnetic interference (EMI) shield comprising one or more vertical interconnect accesses (vias) each disposed in the fan-out area among the one or more fan-out areas.
   2. The IC of aspect 1, wherein the one or more vias are not electrically coupled to any I/O signal fan-out interconnect among the one or more I/O signal fan-out interconnects.
   3. The IC of any one of aspects 1 and 2, wherein each of the one or more vias is disposed in a same fan-out area on only one side among the plurality of die sides of the IC die.
   4. The IC of any one of aspects 1 and 2, wherein.
a first one or more vias among the one or more vias is disposed in a first fan-out area among the one or more fan-out areas; and
a second one or more vias among the one or more vias is disposed in a second fan-out area among the one or more fan-out areas different from the first fan-out area.
   5. The IC of any one of aspects 1 to 2 and 4, wherein the one or more vias are disposed in each of the one or more fan-out areas disposed on each die side among the plurality of die sides.
   6. The IC of any one of aspects 1 to 5, wherein:
the active semiconductor layer comprises an active surface and an inactive surface opposite the active surface; and
the metallization structure is adjacent to the active semiconductor layer; and
further comprising:
   a conductive layer adjacent to the inactive surface of the active semiconductor layer, the conductive layer electrically coupled to at least one via among the one or more vias.
      7. The IC any one of aspects 1 to 6, wherein:
the metallization structure comprises one or more metallization layers; and
at least one via among the one or more vias is electrically coupled to a ground metal line in a metallization layer among the one or more metallization layers.
   8. The IC of aspect 7, further comprising a metal pillar electrically coupling the ground metal line to the active semiconductor layer.
   9. The IC of any one of aspects 1 to 6, wherein the IC die further comprises a passivation layer disposed between the active semiconductor layer and the metallization structure.
   10. The IC of aspect 9, further comprising a metal pillar extending through the passivation layer and electrically coupling a ground metal line to the active semiconductor layer.
   11. The IC of aspect 7, wherein the metallization structure further comprises a substrate metallization layer comprising at least one substrate metal interconnect coupled to the ground metal line, and
further comprising:
   at least one external interconnect coupled to the at least one substrate metal interconnect.
      12. The IC of any one of aspects 1 to 11 integrated into a device selected from the group consisting of: a set top box; an entertainment unit; a navigation device; a communications device; a fixed location data unit; a mobile location data unit; a global positioning system (GPS) device; a mobile phone; a cellular phone; a smart phone; a session initiation protocol (SIP) phone; a tablet; a phablet; a server; a computer; a portable computer; a mobile computing device; a wearable computing device; a desktop computer; a personal digital assistant (PDA); a monitor; a computer monitor; a television; a tuner; a radio; a satellite radio; a music player; a digital music player; a portable music player; a digital video player; a video player; a digital video disc (DVD) player; a portable digital video player; an automobile; a vehicle component; avionics systems; a drone; and a multicopter.
      13. A method of fabricating an integrated circuit (IC), comprising:
forming a metal seed layer disposed on a carrier;
forming an electro-magnetic interference (EMI) shield comprising:
   forming one or more vertical interconnect accesses (vias) in a fan-out area among one or more fan-out areas;
forming an IC die comprising a plurality of die sides, comprising:
   forming an active semiconductor layer disposed in a horizontal plane; and
   forming a metallization structure comprising a plurality of die interconnects electrically coupled to the active semiconductor layer; and
disposing the IC die on the carrier such that the one or more fan-out areas are each adjacent to a different die side among the plurality of die sides.
   14. The method of aspect 13, further comprising:
forming one or more input/output (I/O) signal fan-out interconnects each disposed in the fan-out area among the one or more fan-out areas; and
electrically coupling the one or more I/O signal fan-out interconnects to one or more die interconnects among the plurality of die interconnects.
   15. The method of aspect 14, further comprising not electrically coupling any vias among the one or more vias to the one or more I/O signal fan-out interconnects.
   16. The method of any one of aspects 13 to 15, wherein forming the one or more vias in the fan-out area among the one or more fan-out areas comprises:
disposing a passivation layer on the metal seed layer;
patterning the passivation layer to form one or more openings in the passivation layer such that each opening among the one or more openings is disposed in the fan-out area among the one or more fan-out areas; and
disposing a metal material in the one or more openings to form the one or more vias.
   17. The method of aspect 16, further comprising removing the metal seed layer.
   18. The method of any one of aspects 16 and 17, further comprising disposing an overmolding compound above the carrier and over the one or more vias and the IC die.
   19. The method of aspect 18, further comprising grinding down a top surface of the overmolding compound to a top surface of the one or more vias to expose the top surface of the one or more vias.
   20. The method of aspect 19, further comprising removing the carrier.
   21. The method of any one of aspects 13 to 20, further comprising forming a conductive layer adjacent to an inactive surface of the active semiconductor layer and electrically coupled to at least one via among the one or more vias.
   22. The method of any one of aspects 13 to 21, wherein forming the metallization structure comprises:
forming a first metallization layer comprising a ground metal line electrically coupled to the one or more vias; and
forming a second metallization layer comprising the plurality of die interconnects electrically coupled to the active semiconductor layer.

What is claimed is:

1. An integrated circuit (IC), comprising:
an IC die comprising a plurality of die sides, the IC die comprising:
an active semiconductor layer disposed in a horizontal plane; and
a metallization structure comprising a plurality of die interconnects electrically coupled to the active semiconductor layer;
one or more input/output (I/O) signal fan-out interconnects each disposed in a fan-out area among one or more fan-out areas each adjacent to a different die side among the plurality of die sides of the IC die in the horizontal plane, the one or more I/O signal fan-out interconnects electrically coupled to one or more die interconnects among the plurality of die interconnects; and
an electro-magnetic interference (EMI) shield comprising one or more vertical interconnect accesses (vias) each disposed in the fan-out area among the one or more fan-out areas.

2. The IC of claim 1, wherein the one or more vias are not electrically coupled to any I/O signal fan-out interconnect among the one or more I/O signal fan-out interconnects.

3. The IC of claim 1, wherein each of the one or more vias is disposed in a same fan-out area on only one side among the plurality of die sides of the IC die.

4. The IC of claim 1, wherein:
a first one or more vias among the one or more vias is disposed in a first fan-out area among the one or more fan-out areas; and
a second one or more vias among the one or more vias is disposed in a second fan-out area among the one or more fan-out areas different from the first fan-out area.

5. The IC of claim 1, wherein the one or more vias are disposed in each of the one or more fan-out areas disposed on each die side among the plurality of die sides.

6. The IC of claim 1, wherein:
the active semiconductor layer comprises an active surface and an inactive surface opposite the active surface; and
the metallization structure is adjacent to the active semiconductor layer; and
further comprising:
a conductive layer adjacent to the inactive surface of the active semiconductor layer, the conductive layer electrically coupled to at least one via among the one or more vias.

7. The IC of claim 1, wherein:
the metallization structure comprises one or more metallization layers; and
at least one via among the one or more vias is electrically coupled to a ground metal line in a metallization layer among the one or more metallization layers.

8. The IC of claim 7, further comprising a metal pillar electrically coupling the ground metal line to the active semiconductor layer.

9. The IC of claim 1, wherein the IC die further comprises a passivation layer disposed between the active semiconductor layer and the metallization structure.

10. The IC of claim 9, further comprising a metal pillar extending through the passivation layer and electrically coupling a ground metal line to the active semiconductor layer.

11. The IC of claim 7, wherein the metallization structure further comprises a substrate metallization layer comprising at least one substrate metal interconnect coupled to the ground metal line, and
further comprising:
at least one external interconnect coupled to the at least one substrate metal interconnect.

12. The IC of claim 1 integrated into a device selected from the group consisting of: a set top box; an entertainment unit; a navigation device; a communications device; a fixed location data unit; a mobile location data unit; a global positioning system (GPS) device; a mobile phone; a cellular phone; a smart phone; a session initiation protocol (SIP) phone; a tablet; a phablet; a server; a computer; a portable computer; a mobile computing device; a wearable computing device; a desktop computer; a personal digital assistant (PDA); a monitor; a computer monitor; a television; a tuner; a radio; a satellite radio; a music player; a digital music player; a portable music player; a digital video player; a video player; a digital video disc (DVD) player; a portable digital video player; an automobile; a vehicle component; avionics systems; a drone; and a multicopter.

13. A method of fabricating an integrated circuit (IC), comprising:
forming a metal seed layer disposed on a carrier;
forming an electro-magnetic interference (EMI) shield comprising:
forming one or more vertical interconnect accesses (vias) in a fan-out area among one or more fan-out areas;
forming an IC die comprising a plurality of die sides, comprising:
forming an active semiconductor layer disposed in a horizontal plane; and
forming a metallization structure comprising a plurality of die interconnects electrically coupled to the active semiconductor layer; and
disposing the IC die on the carrier such that the one or more fan-out areas are each adjacent to a different die side among the plurality of die sides.

14. The method of claim 13, further comprising:
forming one or more input/output (I/O) signal fan-out interconnects each disposed in the fan-out area among the one or more fan-out areas; and
electrically coupling the one or more I/O signal fan-out interconnects to one or more die interconnects among the plurality of die interconnects.

15. The method of claim 14, further comprising not electrically coupling any vias among the one or more vias to the one or more I/O signal fan-out interconnects.

16. The method of claim 13, wherein forming the one or more vias in the fan-out area among the one or more fan-out areas comprises:
disposing a passivation layer on the metal seed layer;
patterning the passivation layer to form one or more openings in the passivation layer such that each opening among the one or more openings is disposed in the fan-out area among the one or more fan-out areas; and
disposing a metal material in the one or more openings to form the one or more vias.

17. The method of claim 16, further comprising removing the metal seed layer.

18. The method of claim 16, further comprising disposing an overmolding compound above the carrier and over the one or more vias and the IC die.

19. The method of claim 18, further comprising grinding down a top surface of the overmolding compound to a top surface of the one or more vias to expose the top surface of the one or more vias.

20. The method of claim 19, further comprising removing the carrier.

21. The method of claim 13, further comprising forming a conductive layer adjacent to an inactive surface of the active semiconductor layer and electrically coupled to at least one via among the one or more vias.

22. The method of claim 13, wherein forming the metallization structure comprises:
forming a first metallization layer comprising a ground metal line electrically coupled to the one or more vias; and
forming a second metallization layer comprising the plurality of die interconnects electrically coupled to the active semiconductor layer.
